(19) United States
(12) Patent Application Publication
(10) Pub. No.: US 2017/0133966 A1
(43) Pub. Date: May 11, 2017

(54) RESONANT FREQUENCY SEARCH FOR RESONANT ACTUATORS

(71) Applicant: QUALCOMM Incorporated, San Diego, CA (US)

(72) Inventors: Qadeer Khan, Bangalore (IN); Sandeep Dhar, San Diego, CA (US)

(21) Appl. No.: 14/936,374

(22) Filed: Nov. 9, 2015

(51) Int. Cl. H02P 25/032; G01R 19/165

(52) U.S. Cl. CPC H02P 25/032; G01R 19/16547

(57) ABSTRACT

The embodiments described herein relate to an improved system and algorithm for searching for a resonant frequency of a resonant actuator where the error between the drive frequency of the LRA and the resonant frequency of the LRA is large. In one embodiment, the drive frequency of a resonant actuator is set to an initial drive frequency, which is applied to the LRA. An induced voltage on the resonant actuator crosses can then be detected crossing a threshold voltage after the drive signal is turned off. If crossing the threshold voltage is not detected, the system is configured to sweep through a plurality of drive frequencies until the induced voltage on the resonant actuator is detected crossing the threshold voltage. This can be accomplished by repeatedly adjusting the drive frequency by a predefined incremental frequency ΔF and determining when the induced voltage on the LRA crosses the threshold voltage.

### FIELD OF THE INVENTION

At least certain embodiments disclosed herein relate generally to electronic systems, and more particularly to an improved resonance frequency search algorithm and circuit for driving resonant actuators.

### BACKGROUND

Resonant actuators are alternating current (AC) motors that are often employed to provide feedback in many modern applications utilizing haptic devices (e.g., to provide vibration in a mobile device, etc.). FIG. 1A depicts a block diagram of an example electro-mechanical actuator of which a linear resonant actuator (“LRA”) is one example. Electro-mechanical actuators typically include an inductive coil, such as a voice coil, a magnet, a mass, and a spring. Circuit 100 depicts a linear resonant actuator where a magnetic field is generated by driving coil 101 with a drive signal on wires 102a and 102b. The magnetic field interacts with a magnet 105 in a central region 104 of a mass 103 and creates enough force to move mass 103. The mass 103 and magnet 105 are further suspended on a spring 106 inside a casing 108. As the magnetic field varies with the applied drive signal, the magnet 105 and mass 103 move as they interact with the spring 106, which creates vibration.

A resonant actuator may be modeled as a high-Q mechanical vibration module that has a resonance frequency. Since resonant actuators are high-Q systems, they require auto resonance calibration to drive the actuator at or very near its resonance frequency. FIG. 1B depicts an example resonant frequency response graph showing vibration amplitude as a function of drive frequency. As can be seen, a small drift in the drive frequency can cause a significant drop in the vibration strength of the resonant actuator.

Traditionally, drive circuits have attempted to drive actuators at their self-resonance frequency to achieve a desired mechanical vibration. A variety of factors can cause the resonant frequency to drift away from its nominal value. Drift may occur due to, for example, temperature, aging, orientation, and mechanical tolerances, etc. In some cases, drift may change the resonant frequency by as much as 10% for the combined effects mentioned above. When the drive frequency differs from the resonant frequency by even 2-3%, the vibration strength may drop by as much as 50%.

In cases where the resonant actuator is driven at a frequency that is significantly different from its natural resonance frequency, then the resonant actuator may not cause vibration at all in the haptic device. Since the auto resonance calibration feedback loop is based on the feedback provided by back electromotive force (“EMF”) detection in the resonant actuator, it must vibrate with enough initial strength to produce the back EMF in the first instance. Hence, the initial resonant actuator drive frequency must be driven close enough to its natural resonance frequency (usually within 10%); otherwise, the auto resonance calibration may fail to work.

In addition, the initial resonant actuator drive frequency can be generated either externally or internally. Since the external clock generated from a crystal oscillator is expensive, the initial resonant drive frequency is usually generated from an internal oscillator which may have its own variation as high as 10-16%. This can result in a large error between the initial drive frequency and the resonance frequency such that sufficient back EMF cannot be initially detected. It is therefore necessary to ensure that the resonant actuator is initially driven with enough vibration strength to produce sufficient back EMF for resonant frequency calibration when the error between the initial drive frequency and the actuator resonance frequency is large.

### SUMMARY

The embodiments described herein relate to an improved system and algorithm for searching for a resonant frequency of a resonant actuator. In one embodiment, a method for searching for a resonant frequency of a resonant actuator comprises loading an initial drive frequency configured to drive the resonant actuator at its resonant frequency from a first memory location, setting a drive frequency of the resonant actuator equal to the initial drive frequency, applying a drive signal at the drive frequency to terminals of the resonant actuator for at least a portion of a period of the drive signal, and detecting if an induced voltage on the resonant actuator crosses a threshold voltage after the drive signal is turned off. The method further comprises sweeping through a plurality of drive frequencies until the induced voltage on the resonant actuator is detected crossing the threshold voltage. This can be accomplished by repeatedly adjusting the drive frequency by a predefined incremental frequency.

If the induced voltage on the resonant actuator is not detected crossing the threshold voltage, the method further comprises signaling an occurrence of an auto resonance error, adjusting the drive frequency by the predefined incremental frequency to obtain a calibrated drive frequency, and applying the drive signal to the resonant actuator at the calibrated drive frequency. The calibrated drive frequency can be stored in a second memory location.

If, on the other hand, the induced voltage on the resonant actuator is detected crossing the threshold voltage, the method further comprises reading the drive frequency from the second memory location, storing the drive frequency as a new initial drive frequency in the first memory location, and using the new initial drive frequency in a subsequent drive and resonant frequency search. Once the induced voltage on the resonant actuator is detected crossing the threshold voltage, the drive frequency can be further fine-tuned to match the resonant frequency of the resonant actuator.

In another embodiment a system for searching for a resonant frequency of a resonant actuator is described. The system includes a processor comprising one or more memory locations for storing information to be used during processing, a drive circuit configured to apply a drive signal at a drive frequency to terminals of the resonant actuator for at least a portion of a period of the drive signal, a comparator configured to detect when an induced voltage on the resonant actuator crosses a threshold voltage after the drive signal is turned off, a resonance error detection unit configured to assert an auto resonance error signal when the induced voltage on the resonant actuator is not detected crossing the threshold voltage, and a resonance search controller configured to sweep through a plurality of drive frequencies by repeatedly adjusting the drive frequency by a predefined incremental frequency until the induced voltage on the resonant actuator is detected crossing the threshold voltage.

The resonance search controller is configured to load an initial drive frequency to drive the resonant actuator at its resonant frequency from a first memory location and set the drive frequency equal to the initial drive frequency. When the induced voltage on the resonant actuator is not detected crossing the threshold voltage, the resonance search controller is further configured to adjust the drive frequency by the predefined incremental frequency to obtain a calibrated drive frequency based on receiving the auto resonance error signal from the resonance error detector, and signal the drive circuit to apply the drive signal at the calibrated drive frequency. The calibrated drive frequency can be stored in a second memory location.

When the induced voltage on the resonant actuator is detected crossing the threshold voltage, the resonance search controller is further configured to read the calibrated drive frequency from the second memory location, store the calibrated drive frequency as a new initial drive frequency in the first memory location, and use the new initial drive frequency in a subsequent drive and resonant frequency search.

The system further comprises a clock generator coupled with the drive circuit and the resonance search controller. The clock generator is configured to provide clock signals to be used by the drive circuit to drive the frequency and period of the drive signal.

In further embodiments, a non-transitory computer readable storage medium tangibly embodying computer code for searching for a resonant frequency is disclosed. The computer readable storage medium is configured to perform operations comprising loading an initial drive frequency configured to drive a resonant actuator at its resonant frequency from a first memory location, setting a drive frequency for the resonant actuator equal to the initial drive frequency, applying a drive signal at the drive frequency to terminals of the resonant actuator for at least a portion of a period of the drive signal, and detecting if an induced voltage on the resonant actuator crosses a threshold voltage after the drive signal is turned off. The operations further comprises sweeping through a plurality of drive frequencies until the induced voltage on the resonant actuator is detected crossing the threshold voltage. This can be accomplished by repeatedly adjusting the drive frequency by the predefined incremental frequency.

If the induced voltage on the resonant actuator is not detected crossing the threshold voltage, the operations further comprise signaling an occurrence of an auto resonance error, adjusting the drive frequency by a predefined incremental frequency to obtain a calibrated drive frequency, and applying the drive signal to the resonant actuator at the calibrated drive frequency. If the induced voltage on the resonant actuator is detected crossing the threshold voltage, the operations further comprise reading the calibrated drive frequency from the second memory location, storing the calibrated drive frequency as a new initial drive frequency in the first memory location, and using the new initial drive frequency in a subsequent drive and resonant frequency search.

In yet other embodiments a circuit for searching for a resonant frequency is disclosed comprising means for loading an initial drive frequency configured to drive a resonant actuator at its resonant frequency from a first memory location, means for setting a drive frequency for the resonant actuator equal to the initial drive frequency, means for applying a drive signal at the drive frequency to terminals of the resonant actuator for at least a portion of a period of the drive signal, and means for detecting if an induced voltage on the resonant actuator crosses a threshold voltage after the drive signal is turned off.

If the induced voltage on the resonant actuator is not detected crossing the threshold voltage, the circuit means further comprises a means for signaling an occurrence of an auto resonance error, means for adjusting the drive frequency by a predefined incremental frequency to obtain a calibrated drive frequency, and means for applying the drive signal to the resonant actuator at the calibrated drive frequency. If the induced voltage on the resonant actuator is detected crossing the threshold voltage, the operations further comprise reading the calibrated drive frequency from the second memory location, storing the calibrated drive frequency as a new initial drive frequency in the first memory location, and using the new drive frequency.

The following detailed description and accompanying drawings provide a better understanding of the nature and advantages of the present invention.

### BRIEF DESCRIPTION OF THE DRAWINGS

For a better understanding of at least certain embodiments, reference will be made to the following detailed description, which is to be read in conjunction with the accompanying drawings.

FIG. 1A depicts a block diagram of an example electro-mechanical actuator of which a linear resonant actuator (“LRA”) is one example.

FIG. 1B depicts an example resonant frequency response graph showing vibration amplitude as a function of drive frequency.

FIG. 2 depicts a block diagram of an example actuator drive circuit configuration.

FIG. 3 depicts an example timing diagram or drive voltage and zero crossing detection according to one embodiment.

FIG. 4 depicts an example of voltage and zero crossing detection according to another example embodiment.

FIG. 5A depicts an example block diagram of a hardware implementation of an embodiment of a circuit for searching for a resonance frequency of a resonance actuator.

FIG. 5B depicts an example block diagram of an embodiment of a resonance search controller designed according to the techniques described herein.

FIG. 5C depicts an example flow diagram of an embodiment of a state machine configured to search for a resonance frequency of a resonance actuator.

FIG. 6 depicts a flow chart of an example embodiment of a process for searching for a resonance frequency of a resonant actuator.

FIG. 7A depicts a flow chart of an example embodiment of a process for searching for a resonance frequency of a resonance actuator.

FIG. 7B depicts a flow chart of an example embodiment of a process for searching for a resonance frequency of a resonance actuator.

### DETAILED DESCRIPTION

The present disclosure pertains to an improved resonance frequency search algorithm and system for driving resonant actuators. Throughout this description, for the purposes of explanation, numerous specific details are set forth in order to provide a thorough understanding of the present invention. It will be apparent to one skilled in the art, however, that the techniques described herein may be practiced without some of these specific details. In other instances, well-known structures and devices may be shown in block diagram form to avoid obscuring the underlying principles of the invention.

Provided below is a description of an example system upon which the embodiments of the invention described herein may be implemented. Although certain elements may be depicted as separate components, in some instances one or more components may be combined into a single device or system. Likewise, although certain functionality may be described as being performed by a single element or component within the system, the functionality may in some instances be performed by multiple components or elements working together in a functionally coordinated manner.

The embodiments described herein relate to an improved system and algorithm for searching for a resonant frequency of a resonant actuator. The induced voltage on the resonant actuator is from the back EMF it generates. As discussed above, the resonant frequency of the resonant actuator can drift over time based on temperature, aging, orientation, and mechanical tolerances, etc., which can cause a significant drop in vibration strength of the resonant actuator. It is therefore important that the drive frequency of the resonant actuator be adjusted as necessary to generate sufficient back EMF to calibrate its resonant frequency.

At least certain of the embodiments described herein are configured to sweep through a plurality of drive frequencies by repeatedly adjusting the drive frequency by a predefined incremental frequency ΔF until an induced voltage on the resonant actuator is detected crossing a threshold voltage. In one embodiment, the threshold voltage can be a zero crossing of the voltage HOUTP-HOUTN of the terminals of the resonant actuator. If the induced voltage on the resonant actuator is not detected crossing the threshold voltage, embodiments are configured to signal an occurrence of an auto resonance error, adjust the drive frequency by a predefined incremental frequency ΔF to obtain an updated or calibrated drive frequency, and then to apply the drive signal to the resonant actuator at the updated drive frequency.

The calibrated drive frequency can then be stored in a second memory location, and continuously updated until the induced voltage on the resonant actuator can be detected crossing the threshold voltage. When the induced voltage on the resonant actuator is detected crossing the threshold voltage, the embodiments described herein are configured to read the calibrated drive frequency from the second memory location, store it as a new initial drive frequency in the first memory location, and use the new initial drive frequency in a subsequent drive and resonant frequency search.

In this manner, a coarse adjustment of the initial drive frequency can be used to drive the resonant actuator in systems where there may have been significant drift in the actuator resonant frequency. Once a zero crossing of the induced voltage on the resonant actuator is detected, the embodiments are configured to resume normal calibration operations to fine-tune the drive frequency to match the resonant frequency of the resonant actuator. Various prior art methods have been proposed to perform such fine-tuning to calibrate the drive frequency to match the resonant frequency of the actuator once the initial drive frequency generates enough induced voltage (back EMF) in the resonant actuator for calibration operations to proceed. One such method includes the method described in U.S. Patent Publication No. 2015/0069939 to Khan et al., the disclosure of which is incorporated herein by reference in its entirety.

In one embodiment, the resonant actuator comprises a linear resonant actuator (“LRA”). Since LRAs comprise a high-Q system, they require an auto resonance calibration to drive the LRA at its self-resonance frequency. When the LRA is initially driven at a frequency that is substantially different from its self-resonance frequency, the LRA may not vibrate at all. As discussed above, since the auto resonance calibration is based on back EMF detection of the induced voltage on the LRA, it must initially vibrate with enough strength for sufficient back EMF to be detected. Hence, the initial LRA drive frequency must be driven close to its resonance frequency (usually within 10%); otherwise the auto resonance calibration may fail to work.

The embodiments described herein are adapted to search for an initial drive frequency to be applied to the resonant actuator to account for circumstances when the error between the drive frequency and the LRA's resonant frequency is large. While this typically occurs during initialization of the LRA, it can also occur in other circumstances, including during operation of the LRA. The proposed resonance search algorithm ensures the LRA is driven with enough vibration strength to produce the requisite back EMF. This can be accomplished by first setting the LRA drive frequency to an initial drive frequency (e.g., such as the drive frequency provided in the LRA manufacture's data sheet or specification), and then sweeping through a plurality of predefined incremental frequencies ΔF until a frequency is reached that is close enough to the resonance frequency of the LRA to produce a sufficient amount of back EMF to calibrate the drive frequency. Once the auto calibration process described herein is successful and enough back EMF is generated from the LRA, the drive frequency can be further fine-tuned to the natural resonance frequency of the LRA according to prior art methods.

The algorithm configured according to the embodiments described herein works as a coarse tuning of the LRA drive frequency to ensure enough back EMF is generated to make the auto resonance calibration successful. This can be achieved by varying the LRA drive frequency in predefined frequency increments ΔF (e.g., ±5-10%), and then determining if the auto resonance calibration was successful. In one embodiment, an auto resonance error status register can be provided to store the current state of the error signal, for example, as a status bit “S”.

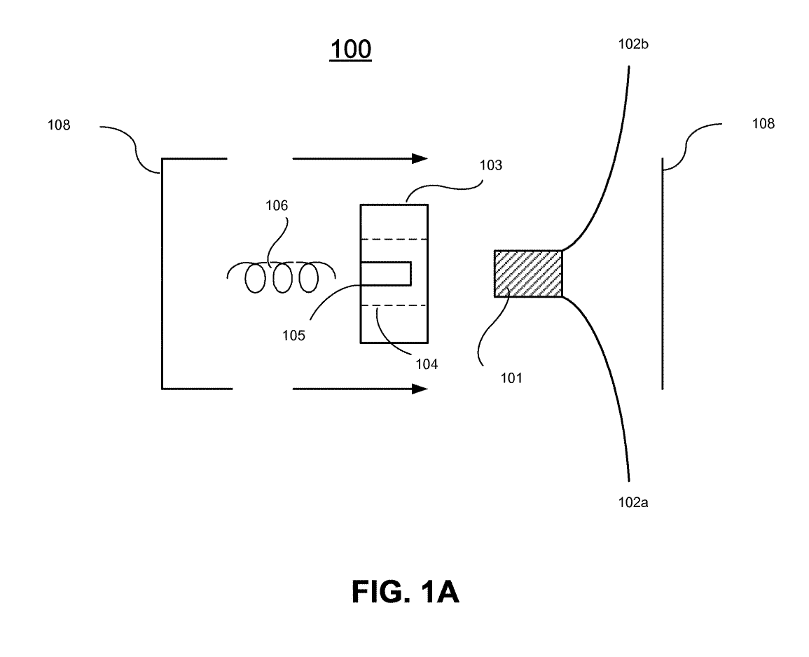

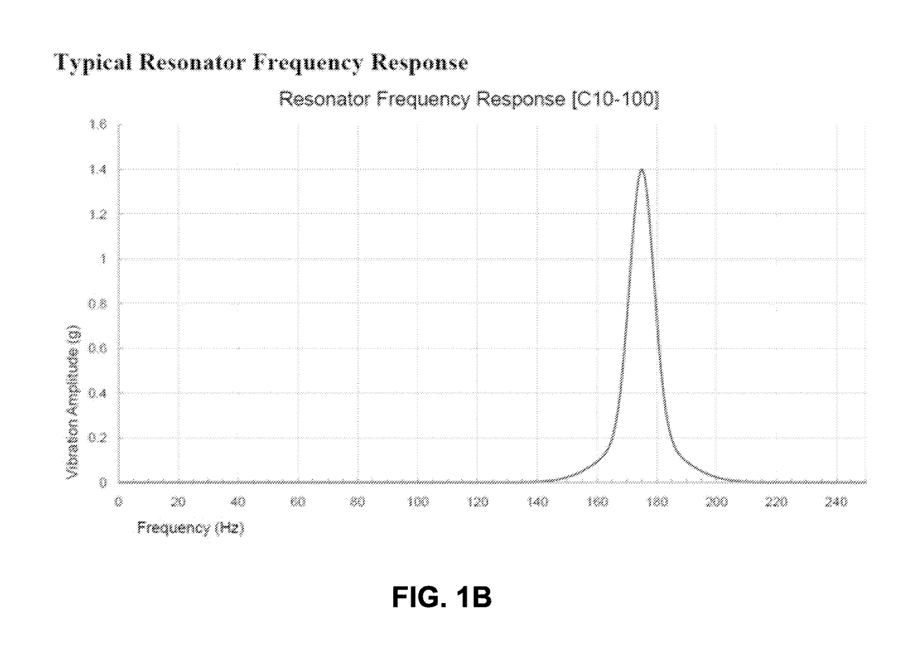

Embodiments of the techniques described herein include systems and algorithms for driving electro-mechanical actuators such as LRA 100 shown in FIG. 1A. Some embodiments may include a method where a periodic drive signal is applied to an electro-mechanical actuator having a resonant frequency. Movement caused by the drive signal causes an induced voltage in the actuator. The induced voltage comprises a back EMF voltage that pushes against current in an inductive coil.

Circuitry may be provided to detect when the back EMF on the resonant actuator crosses a threshold voltage after the drive signal is turned off. In one embodiment, the threshold voltage comprises a zero crossing of the induced voltage across the actuator generated as a result of vibration by the actuator. For example, when the actuator drive signal is turned off, the drive circuit can be placed in a high impedance state and the movement of the actuator generates the back EMF (induced voltage). The point at which the induced voltage crosses the threshold voltage corresponds to the crossing point of resonant frequency of the actuator and may be used to trigger the drive signal so that phase and frequency of the drive signal is aligned with the resonant frequency and a phase of the actuator. This technique has the advantage of searching for and finding a drive frequency for driving the actuator at its natural resonant frequency even as the resonant frequency drifts over time. The drive signal frequency may be set by detecting zero crossings at each cycle.

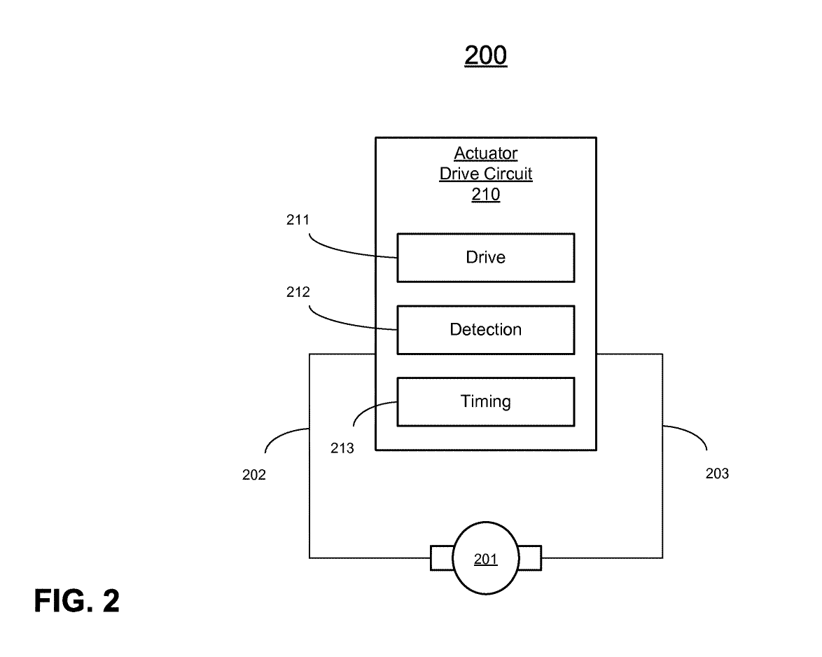

FIG. 2 depicts a block diagram of an example actuator drive circuit configuration. In the illustrated embodiment, the electro-mechanical actuator 201 may include two terminals 202 and 203 for receiving drive signals from actuator drive circuit 210. The actuator drive circuit 210 may include a drive circuit 211, detection circuit 212, and timing circuit 213. Drive circuit 211 generates drive signals to actuator terminals 202 and 203 to generate a current for producing motion in the actuator 201. Detection circuit 212 is configured to detect back EMF voltage on drive terminals 202 and 203 and to detect when zero crossings occur. Timing circuit 213 may be configured to generate timing signals based on the detected voltages to control the drive signal generated by drive circuit 211. Timing circuit 213 can be configured to assert the drive signal based on when the induced voltage crosses the threshold to align the frequency and phase of the drive signal with the resonant frequency and a phase of the actuator.

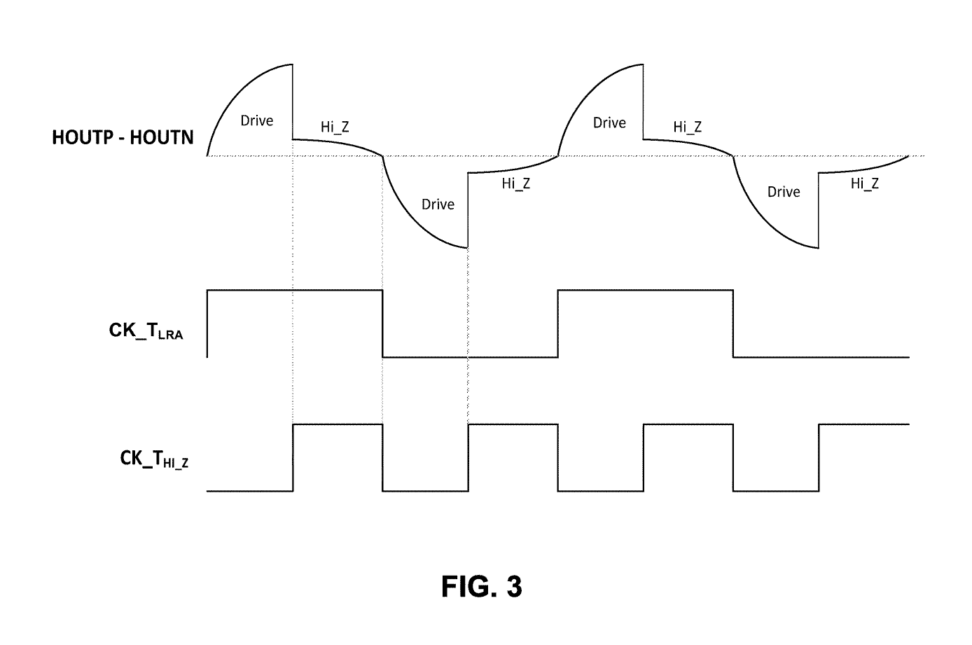

FIG. 3 depicts an example timing diagram or drive voltage and zero crossing detection according to one embodiment. In this example, the drive signal is the differential signal HOUTP-HOUTN applied across two terminals of the actuator. Here, the drive signal is applied during a portion of each half cycle of a vibration period of the actuator. Other portions less than, greater than, or equal to a half cycle may also be used, and may be programmable.

The vibration during the other portion of every half cycle is maintained by the mechanical property of a spring in the actuator. The drive signal in this example is a partial sinusoidal analog signal. In the illustrated embodiment, after a quarter period, the drive signal is turned off and the terminals of the actuator are placed in a high impedance (“Hi_Z”) state. When the terminals transition to high impedance, the voltage on the actuator terminals transitions from the drive signal voltage to the induced voltage caused by the mechanical movement of the actuator itself (i.e., back EMF). Depending on polarity, the induced voltage either increases or decreases with time, and eventually crosses a threshold voltage based on the differential voltages HOUTP-HOUTN across the actuator terminals. The threshold voltage may correspond to when the differential voltage HOUTP-HOUTN goes to zero (i.e., a zero crossing). Such a zero crossing may be detected after each drive cycle. Detection of a zero crossing may trigger the start of the drive signal for the next cycle, which is opposite in polarity compared to the previous quarter cycle.

As illustrated in FIG. 3, the zero crossings may be used to set the period of a clock signal CK_T_{LRA} adapted for driving the LRA, and for setting the period of another clock signal CK_T_{HI}_{_}_{Z} adapted for placing the drive signal in a high impedance state. In an alternate embodiment, the individual clock signal CK_T_{LRA} may be configured both to drive the LRA (e.g., when the drive signal is at positive polarities) and for placing the drive signal in a high impedance state (e.g., when the drive signal is at negative polarities) using the positive and negative edges of the same clock signal, or some combination thereof.

Likewise, the clock signal CK_T_{HI}_{_}_{Z} can be used to set the duration of the drive and high impedance (Hi_Z) signals so that the duration of the drive and Hi_Z signals is more closely aligned with the programmed portion of resonant period of the actuator. Accordingly, if the resonant frequency drifts, the zero crossings also change in response, and the duration of the drive signal tracks the resonant period to maintain the programmed portion of the drive. In cases where there is insufficient back EMF generated for a zero crossing to be detected, the embodiments described herein are configured to detect this condition and to sweep through a plurality of incremental frequencies ΔF until an appropriate frequency can be reached that is close enough in proximity to the resonant frequency of the actuator to produce sufficient vibration in the LRA.

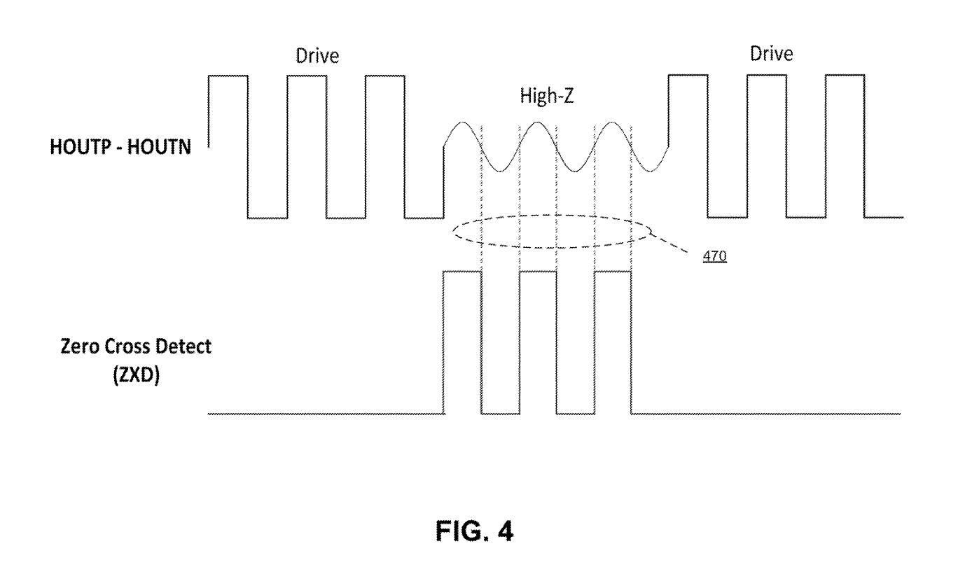

Auto resonance calibration is based on back EMF zero cross detection. FIG. 4 depicts an example of voltage and zero crossing detection according to another example embodiment. When the drive frequency HOUTP-HOUTN is turned off and the actuator is placed in high impedance mode, the induced voltage on the resonant actuator continues to oscillate based on the back EMF generated by the actuator. Each time the induced voltage across terminals HOUTP-HOUTN crosses zero, a zero cross detect (“ZXD”) signal can be generated at the appropriate instances 470 as shown in FIG. 4. If a zero crossing is detected during the Hi_Z state, then the frequency of the zero crossing is equal to the resonance frequency of the resonant actuator. In cases where there is insufficient back EMF generated for a zero crossing to be detected, the embodiments described herein are configured to detect this condition and to sweep through a plurality of incremental frequencies ΔF until an appropriate frequency can be reached that is close enough in proximity to the resonant frequency of the actuator to produce sufficient vibration in the LRA.

### I. Exemplary System

Provided below is a description of an example system which may be implemented by the embodiments described herein. Although certain elements may be depicted as separate components, in some instances one or more of the components may be combined into a single component or device. Likewise, although certain functionality may be described as being performed by a single element or component within the system, the functionality may in some instances be performed by multiple elements or components working together in a functionally coordinated manner.

In addition, hardwired circuitry may be used independently or in combination with software instructions to implement the techniques described herein. The described functionality may be performed by custom hardware components containing hardwired logic for performing operations, or by any combination of hardware and programmed computer components. The techniques described herein are not limited to any specific combination of computer hardware or software components.

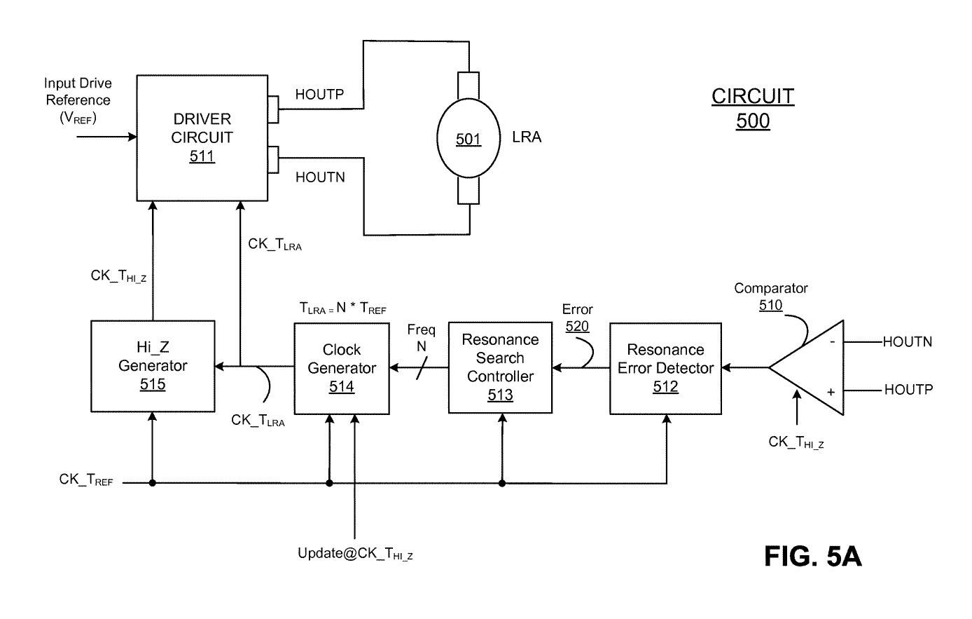

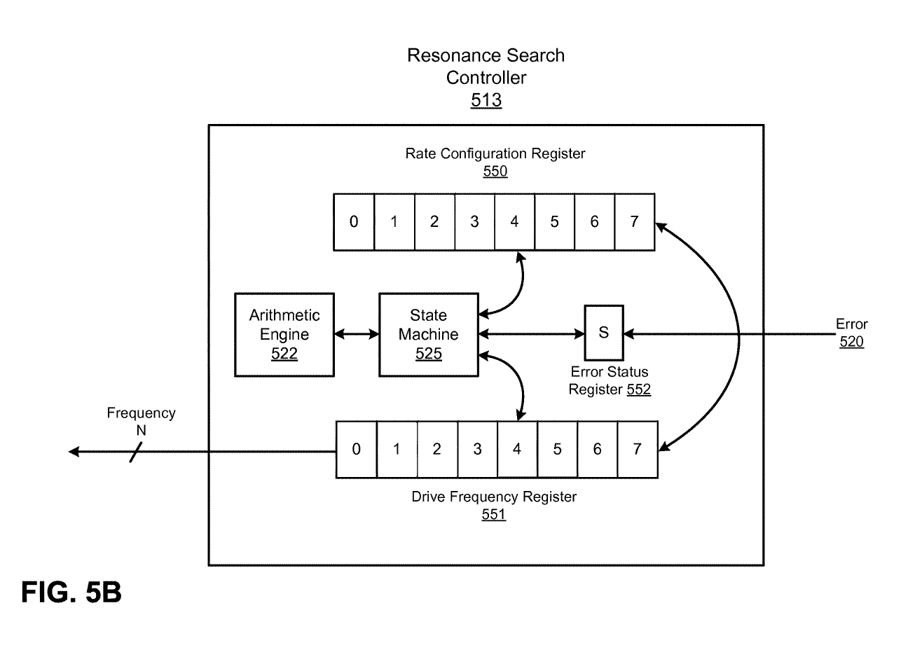

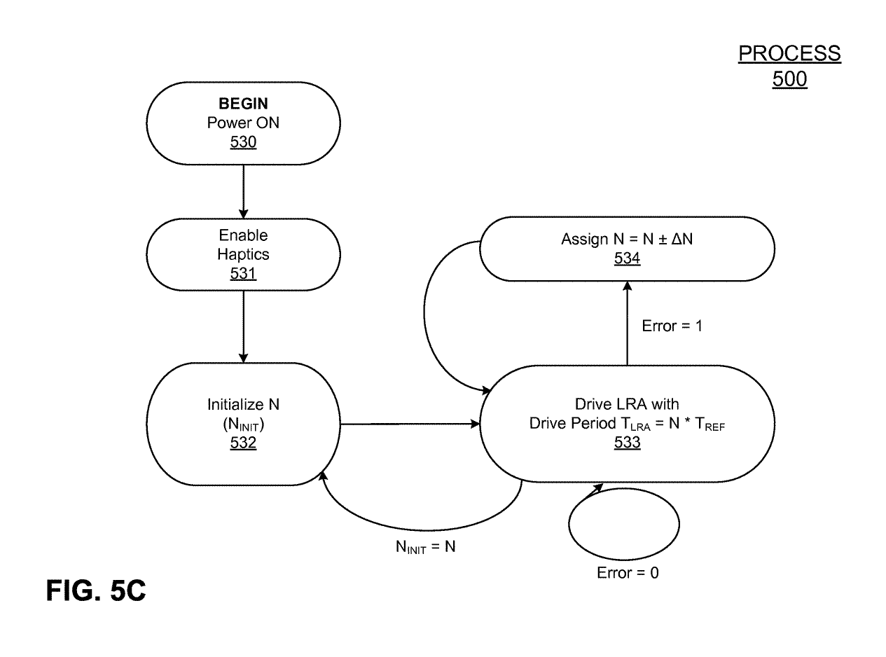

FIG. 5A depicts an example hardware implementation of an embodiment of a circuit configured for searching for a resonance frequency of a resonance actuator. As noted above, the techniques and components described herein can be implemented in hardware or software, or any combination thereof. In the illustrated embodiment, circuit 500 includes a LRA 501 with signals HOUTP and HOUTN coupled with terminals of the drive circuit 511 configured to drive the LRA 501. In one embodiment, drive circuit 511 is configured to drive the terminals HOUTP and HOUTN of the LRA 501 with a waveform similar to the one shown in FIG. 3. Other waveforms and waveform types can be used with the embodiments described herein. Circuit 500 further includes a comparator 510, a resonance error detector 512, a resonance search controller 513, a clock generator 514, and a high impedance (Hi_Z generator) 515.

Vibration is a function of both drive voltage and drive frequency of an LRA. LRA 501 may be driven at an initial drive frequency based on initial data stored in the system (or provided to the system). For example, the LRA may be driven at an initial drive frequency based upon a value given by a manufacturer's datasheet or specification for the LRA. In other cases, the initial LRA drive frequency may be previously calculated. In one embodiment, the initial LRA drive frequency can be programmed into one or more rate configuration registers RATE_CFG. The initial drive frequency can be determined using the following equation:

LRA drive frequency (Hz)=(19.2*10⁶)/96*1/(LRA drive period);
where the reference clock signal CK_T_{REF} is equal to 19.2 MHz

Note, however, that the frequency of the clock signal CK_T_{REF} may be different from 19.2 MHz based on the system clock used. The dividing factor 96 can vary and is allocated based on the desired incremental step size for adjusting the drive frequency. The step size may vary based on the particular requirements of the system. The frequency can be in the range of, for example, 50 Hz to 300 Hz, and the maximum step size can be 0.5 Hz, which translates into a 5 μs (microseconds) step size at 200 KHz. The LRA drive period is used to determine the drive frequency of the LRA. The LRA drive frequency is generated by dividing the above equation with the 200 KHz clock (19.2 MHz/96 ) by the LRA drive period, which can be programmed.

The above expression is based on the assumption that 19.2 MHz clock signal is constant; however, in operation the internal clock signal may have variation as high as ±16%. Adding another 10% inaccuracy coming from LRA 501 itself may cause the initial LRA drive frequency to be off by as much as 26% from the actual LRA resonance frequency.

Circuit 500 includes a comparator 510 that can be configured to detect zero crossings of the induced voltage across terminals HOUTP-HOUTN of the LRA 501 during times when the drive signal is turned off. As discussed above, when the drive signal is turned off the terminals HOUTP and HOUTN of the resonant actuator 501 are configured to enter the high impedance (Hi_Z) state. In the Hi_Z state, the resonant actuator 501 begins to generate a self-induced voltage across its terminals HOUTP and HOUTN that oscillates at the LRA's resonant frequency. In one embodiment, comparator 510 comprises an operational amplifier that is configured to receive signal HOUTN at its inverting (-) input terminal and signal HOUTP at its non-inverting (+) input terminal. Comparator 510 also receives a clock signal CLK_T_{HI}_{_}_{Z} for synchronizing comparator operations.

Comparator 510 is coupled with (directly or indirectly through intermediary circuitry) a resonance error detection unit (detector) 512 that is adapted to generate an auto resonance error signal 520 whenever a threshold voltage crossing fails to be detected on the terminals HOUTP and HOUTN of the LRA 501. The resonance error detector 512 can be synchronized with a system reference clock signal CK_T_{REF} and can determine when sufficient induced voltage generated by the back EMF of the LRA 501 has not been detected after a predefined time interval has passed.

For example with reference to FIG. 3 above, when the drive circuit 511 turns off the drive signal and the circuit enters into the high impedance (Hi_Z) mode after a half period of the clock signal CK_T_{LRA}, a zero crossing for signals HOUTP-HOUTN on the terminals of the LRA 501 should be detected within a predetermined time interval (e.g., within the second half period of the clock signal CK_T_{LRA}). In certain embodiments, referring to FIG. 3 above, if a zero crossing of the signals HOUTP-HOUTN fails to be detected before the falling edge of the clock signal CK_T_{LRA} driving the LRA 501 (or some other preconfigured time interval), then an auto resonance error signal 520 may be asserted by the resonance error detector 512.

The auto resonance error signal 520 indicates that the induced voltage on the LRA 501 has not been detected crossing the threshold voltage (e.g., zero crossing) within the preconfigured time interval. In such circumstances, the resonance search controller 513 can determine that the LRA 501 is not being driven with a frequency close enough to its self-resonant frequency to provide enough back EMF to calibrate the LRA 501. The auto resonance error signal 520 can be provided to the resonance search controller 513 as shown in the illustrated embodiment for the purpose of initiating the resonant frequency search operations described herein.

If the auto resonance error signal 520 is received at the resonance search controller 513, the resonance search controller 513 can be configured to sweep through a plurality of incremental frequencies ΔF in response to the auto resonance error signal 520 until a drive frequency is reached whereby a zero crossing threshold voltage can be detected by the comparator 510. If, on the other hand, an auto resonance error signal 520 is not received at the resonance search controller 513 (or is zero), then the circuit 500 continues with normal resonant frequency calibration operations according to prior art techniques.

The resonance search controller 513 is configured to receive the error signal 520 and perform the algorithm described herein in response. One embodiment of the resonance search controller 513 is shown in FIG. 5B, which depicts an example block diagram of an embodiment designed according to the techniques described herein. As shown in FIG. 5B, the resonance search controller 513 includes a rate configuration register 550, a drive frequency register 551, an error status register 552, a state machine 525, and an arithmetic engine 522. In one embodiment, the error status register could also be an error interrupt signal.

The rate configuration register 550 is configured to store the initial drive frequency for the LRA 501. This may be provided in a manufacturer's data sheet or previously calculated. The drive frequency register 551 is configured to store the intermediate drive frequencies used by the resonance frequency search algorithm during resonant frequency calibration operations. Initially, when it is determined that the induced voltage across the LRA 501 is insufficient to generate enough back EMF for detection, the arithmetic engine 522 is configured to add (or subtract) a predetermined incremental frequency ΔF to (from) the initial drive frequency stored in the rate configuration register 550. The resulting frequency is then stored in the drive frequency register 551 and used for the next cycle of the resonant frequency search algorithm.

Thereafter, for each cycle of the resonant frequency search algorithm, an incremental frequency ΔF can be added to (or subtracted from) the previous drive frequency stored in the drive frequency register 551 until the auto resonance search process converges. The arithmetic engine 522 can be configured to perform the arithmetic operations for the drive frequency calculations. “N” digital code bits representing the drive frequency (or drive period) that are stored in the drive frequency register 551 can then be provided to the clock generator 514 for use in setting the drive frequency (and drive period) of the LRA for the next cycle of the resonance frequency search process.

In one embodiment, the resonant frequency search process can be performed utilizing the state machine 525 stored in the resonance search controller 513. FIG. 5C depicts an example flow diagram of an embodiment of the state machine 525 configured to perform resonance frequency search operations for LRA 501. In the illustrated embodiment, process 500 begins at operation 530 when the device is first powered on. The haptic device(s) can then be enabled (operation 531), and the integer “N” can be initialized to N_{INIT} corresponding to the initial drive period for the LRA 501 (operation 532). LRA 501 can then be driven with the initial drive period T_{LRA} equal to the integer N multiplied by the period T_{REF} of a reference clock signal CK_T_{REF} (operation 533). Thus, the initial drive period of the LRA 501 can be given by setting the drive period T_{LRA} equal to N*T_{REF}, where T_{REF} is the period of the reference clock signal CK_T_{REF}. The arithmetic engine 522 coupled with the state machine 525 can be configured to perform these multiplication operations.

When no error signal 520 is received (or the error signal is set to zero) by the resonance search controller 513, the LRA 501 continues to be driven by the drive period T_{LRA} equal to N_{INIT}T_{REF}. But when the error signal 520 is received by the resonance search controller 513, the integer N is incremented or decremented by ΔN by assigning N equal to N ±ΔN (operation 534). The resonance search controller 513 receives the error signal 520 from the resonance error detector 512, and upon receipt the resonance search controller 513 is configured to set a status bit “S” in the error status register 552. The resonance search controller 513 is further configured to clear the status bit S when the error signal 520 is not received. Resonance search operations continue until the error signal 520 is no longer received and/or the status bit S is cleared.

Process 500 continues by driving the LRA with the calibrated drive period T_{LRA} equal to (N±ΔN)*T_{REF} until the resonance search process is successful. Once the resonance frequency search process converges to a frequency sufficient to produce enough induced voltage on the LRA 501 to be detected, the drive frequency can be stored back into the rate configuration register 550 for use as the new initial drive frequency in subsequent drive and resonance frequency search operations. The integer N_{INIT} can be set to the corresponding value of integer N and the LRA drive period T_{LRA} can be updated so that when haptics are enabled the next time, the driver circuit starts with the correct frequency.

Referring back to the illustrated embodiment of FIG. 5A, circuit 500 further includes a clock generator 514 and a Hi_Z generator 515. The clock generator 514 is configured to receive the N bits representing the drive period (frequency) from the drive frequency register 551 for use in the next cycle of the resonant search algorithm. Clock generator 514 also receives the reference clock signal CK_T_{REF} as well as updates to the high impedance clock signal CK_T_{HI}_{_}_{Z}. The clock generator 514 is configured to output a clock signal CK_T_{LRA} driven at the current drive period T_{LRA}. This clock signal CK_T_{LRA} is provided to the driver circuit 511 to adjust the drive signal of the LRA 501 accordingly. In addition, the clock signal CK_T_{LRA} is provided to the Hi_Z generator 515, which is configured to generate the clock signal CK_T_{HI}_{_}_{Z}. The clock signal CK_T_{HI}_{_}_{Z} is also provided to the driver circuit 511 to place the LRA 501 into the high impedance state.

### II. Exemplary Processes

The processes described below are exemplary in nature and are provided for illustrative purposes and not intended to limit the scope of the embodiments described herein to any particular example embodiment. For instance, processes in accordance with some embodiments may include or omit some or all of the operations described below, or may include steps in a different order than described herein. The particular processes described are not intended to be limited to any particular set of operations exclusive of all other potentially intermediate operations.

In addition, the operations may be embodied in computer-executable code, which causes a general-purpose or special-purpose computer to perform certain operations. In other in stances, these operations may be performed by specific hardware components or hardwired circuitry, or by any combination of programmed computer components and custom hardware circuitry.

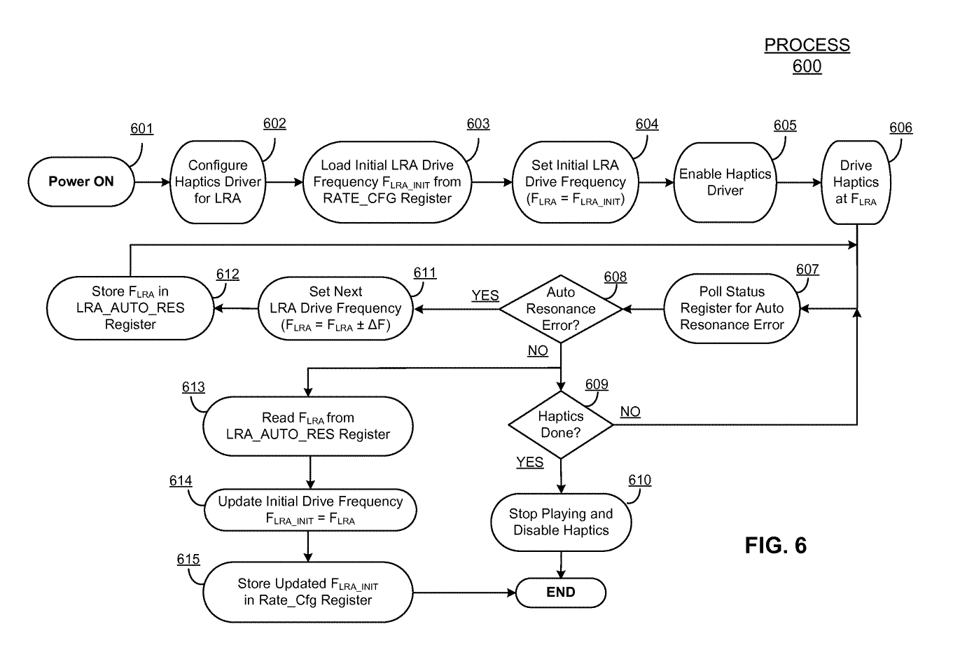

FIG. 6 depicts an example embodiment of a circuit of an algorithm for searching for a resonance frequency of a resonance actuator. The resonance search algorithm is based on re-programming the LRA drive frequency by +/−5-10% and checking to determine if auto resonance calibration was successful (by polling the auto resonance error status bit or issuing an interrupt signal). In the illustrated embodiment, process 600 begins by powering on (operation 601) and configuring the haptics driver for the LRA (operation 602). The initial LRA drive frequency F_{LRA}_{_}_{INIT} can be programmed into a rate configuration register “RATE_CFG” based on the equation given above. F_{LRA}_{_}_{INIT} can then be loaded from the rate configuration register “RATE_CFG” (operation 603). The drive frequency F_{LRA} used by the resonant search algorithm can then be set to the initial F_{LRA}_{_}_{INIT} drive frequency stored in the RATE_CFG register (operation 604).

The haptics driver can then be enabled (operation 605) and driven at the drive frequency F_{LRA} (operation 606). The auto resonance error status register can be polled (operation 607) to determine if an auto resonance error has occurred (operation 608). If no resonance error has occurred, then process 600 proceeds to operation 609 by checking to see if driving the haptics is complete. If so, the process stops playing and disables the haptics at operation 610. If driving the haptics is not complete, the process repeats by continuously checking for an auto resonance error in operations 607 and 608.

If an auto resonance error is detected at operation 608, process 600 continues by updating the drive frequency F_{LRA} for the next cycle of process 600. Process 600 updates the LRA drive frequency F_{LRA} by setting it equal to the previous F_{LRA} plus an additional incremental or detrimental frequency adjustment ΔF (operation 611). This updated drive frequency F_{LRA}+ΔF can be stored in a drive frequency register “LRA_AUTO_RES” (operation 612) and then used as the next F_{LRA} in the following cycle of process 600 as shown until the process converges. In one embodiment, the LRA_AUTO_RES register stores the frequency calibrated from auto resonance (fine tune) and software can directly write into the RATE_CFG register and update the same for the auto resonance search.

It should be noted that registers RATE_CFG and LRA_AUTO_RES can be utilized to store the various values of the drive frequency during execution of process 600. These registers may be provided on-board a processor in a computer system, or they may be dedicated registers located in the resonance search controller 513, or any combination thereof. They may also be implemented in other memory locations within the computer system such as in system memory, cache, RAM, ROM, etc., or any combination of registers and memory locations. RATE_CFG and LRA_AUTO_RES can also be implemented as simple memory buffers or other similar circuitry configured for storage of data. The embodiments described herein are not limited to any particular type or location of memory for storing the drive frequency values.

LRA_AUTO_RES can be utilized for storing the actual resonance frequency of the LRA determined by auto resonance calibration. While the resonance search is successful/converged and there is no error, then the auto resonance calibration determines the actual resonance frequency and stores it in the LRA_AUTO_RES register. Software can read the LRA_AUTO_RES register and use it as the initial drive frequency when haptics is enabled the next time.

Once the resonance frequency search process 600 converges to a frequency sufficient to produce enough induced voltage on the LRA to be detected, that frequency F_{LRA} can be stored back into register RATE_CFG as a new F_{LRA}_{_}_{INIT} for use as the initial drive frequency in subsequent drive and resonance search operations. As an illustrative example, when the auto resonance error is equal to zero after calibration, then auto resonance is successful and the RATE_CFG register can be updated with the calibrated frequency F_{LRA} stored in LRA_AUTO_RES register. If the auto resonance error is equal to one, then the RATE_CFG register can first be reprogrammed with F_{LRA}_{_}_{INIT} plus 10%, as an example, and the auto resonance error can be checked again. If the auto resonance error is still equal to one, then the RATE_CFG register can be reprogrammed again with F_{LRA}_{_}_{INIT} minus 10% and the auto resonance error can be checked again, and so on. The process repeats with different incremental frequency values (e.g., ±5-15%) until the process converges.

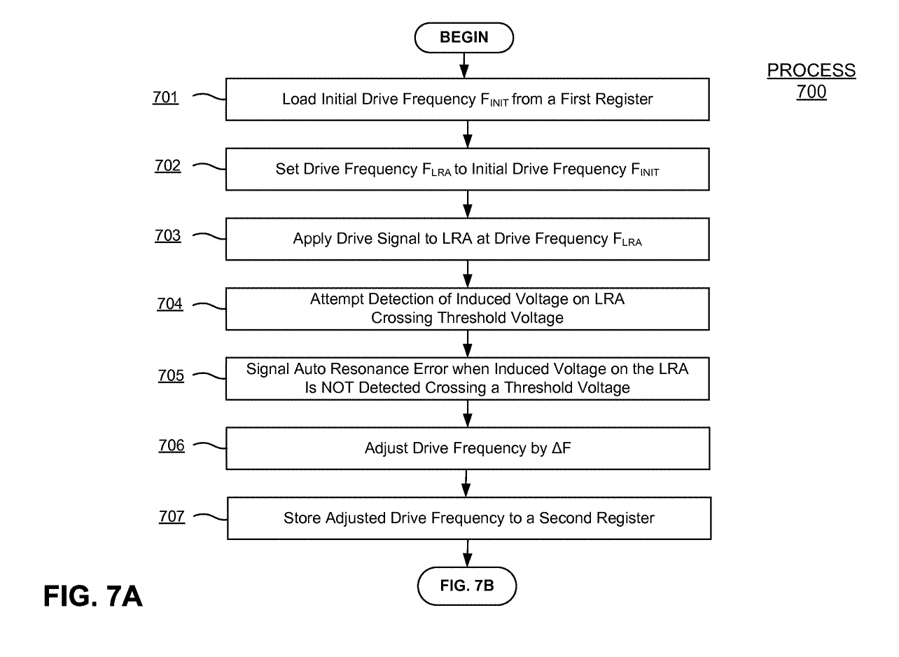

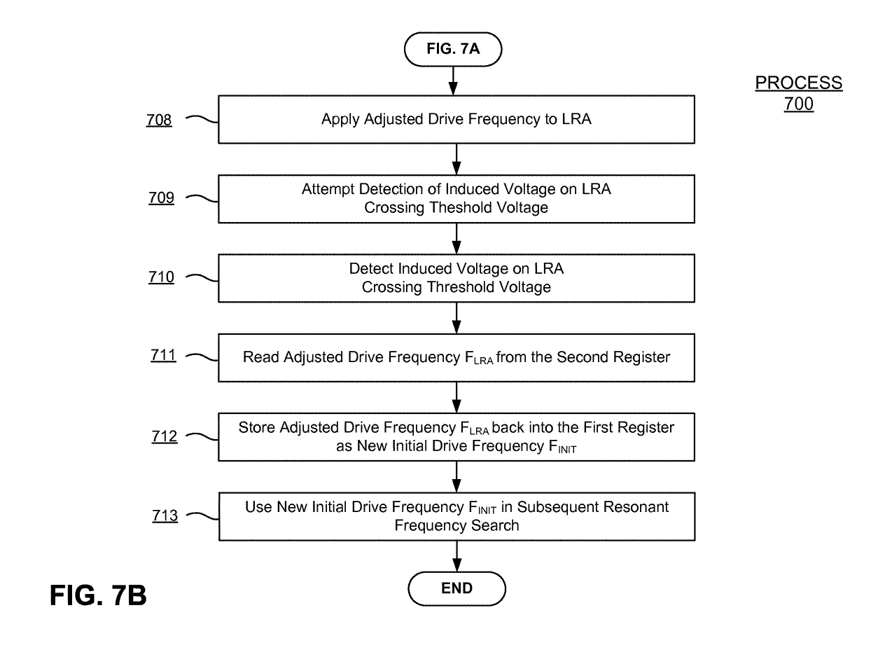

FIG. 7A depicts an example embodiment of a process for searching for a resonance frequency of a resonance actuator. In the illustrated embodiment, process 700 begins at operation 701 by loading the initial drive frequency F_{INIT} from a first register (or other memory location). In one embodiment, the initial drive frequency F_{INIT} can be stored in a rate configuration register RATE_CFG. Process 700 continues by setting the drive frequency F_{LRA} to be used in the resonance frequency search to the initial drive frequency F_{INIT} (operation 702). The drive signal can then be applied to the LRA at the drive frequency F_{LRA} at operation 703.

Process 700 continues at operation 704 by attempting to detect an induced voltage on the LRA crossing a threshold voltage after the drive signal is turned off. When the induced voltage on the LRA is not detected crossing the threshold voltage, an auto resonance error can be signaled (operation 705), the drive frequency F_{LRA} can be adjusted by a predetermined incremental frequency ΔF (operation 706), and the adjusted drive frequency can be stored in a second register (operation 707). In one embodiment, as discussed above the threshold voltage includes a zero crossing of the induced voltage on the terminals of the LRA and the second register includes the LRA_AUTO_RES.

Process 700 continues at FIG. 7B, which depicts an example embodiment of process for searching for a resonance frequency of a resonance actuator. At operation 708, the adjusted drive frequency is applied to the LRA. Process 700 continues by attempting to detect an induced voltage on the LRA crossing a threshold voltage after the drive signal is turned off (operation 709). When the induced voltage on the LRA is detected crossing the threshold voltage (operation 710), the calibrated drive frequency F_{LRA} can be read from the second register (operation 711), stored back into the first register as a new initial drive frequency FINIT (operation 712), and used as in a subsequent drive and resonant frequency search process (operation 713). This completes process 700 according to one example embodiment.

### III. Exemplary Hardware Implementation

Those of skill would further appreciate that the various illustrative logical blocks, modules, circuits, and algorithm steps described in connection with the embodiments disclosed herein may be implemented as electronic hardware, computer software, or combinations thereof. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Persons of skill in the art may implement the described functionality in varying ways for each particular application, but such implementation decisions should not be interpreted as causing a departure from the scope of the exemplary embodiments described herein.

The various illustrative logical blocks, modules, and circuits described in connection with the embodiments disclosed herein may be implemented or performed with a general purpose processor, a Digital Signal Processor (“DSP”), an Application Specific Integrated Circuit (“ASIC”), a Field Programmable Gate Array (“FPGA”) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine, etc. A processor may also be implemented as a combination of computing devices, e.g., a combination of a DSP and a microprocessor, a plurality of microprocessors, one or more microprocessors in conjunction with a DSP core, or any other such configuration.

The steps of a process or algorithm described in connection with the embodiments disclosed herein may be embodied directly in hardware, in a software module executed by a processor, or in a combination of the two. A software module may reside in Random Access Memory (“RAM”), flash memory, Read Only Memory (“ROM”), Electrically Programmable ROM (“EPROM”), Electrically Erasable Programmable ROM (“EEPROM”), registers, hard disk, a removable disk, a CD-ROM, or any other form of storage medium known in the art. An exemplary storage medium is coupled with the processor such that the processor can read information from, and write information to, the storage medium. In the alternative, the storage medium may be integrated into the processor.

To the extent the embodiments described herein are implemented in software, the functions may be stored on or transmitted over as one or more instructions or code on a computer-readable medium. Computer-readable media includes non-transitory computer storage media and communication media including any medium that facilitates transfer of a computer program from one place to another. A storage media may be any available media that can be accessed by a computer. By way of example, such computer-readable media can comprise RAM, ROM, EPROM, EEPROM, CD-ROM or other optical disk storage, magnetic disk storage or other magnetic storage devices, or any other medium that can be used to carry or store desired program code in the form of instructions or data structures and that can be processed by a computer.

Throughout the foregoing description, for the purposes of explanation, numerous specific details were set forth in order to provide a thorough understanding of the invention. It will be apparent, however, to persons skilled in the art that these embodiments may be practiced without some of these specific details. The above examples and embodiments should not be deemed to be the only embodiments, and are presented to illustrate the flexibility and advantages of the present invention. Other arrangements, embodiments, implementations and equivalents will be evident to those skilled in the art and may be employed without departing from the spirit and scope of the invention as defined by the following claims.

What is claimed is:

1. A method of searching for a resonant frequency comprising:
loading an initial drive frequency configured to drive a resonant actuator at its resonant frequency from a first memory location;
setting a drive frequency for the resonant actuator equal to the initial drive frequency;
applying a drive signal at the drive frequency to terminals of the resonant actuator for at least a portion of a period of the drive signal;
detecting if an induced voltage on the resonant actuator crosses a threshold voltage after the drive signal is turned off;
if the induced voltage on the resonant actuator is not detected crossing the threshold voltage, the method further comprises:
signaling an occurrence of an auto resonance error;
adjusting the drive frequency by a predefined incremental frequency to obtain a calibrated drive frequency; and
applying the drive signal to the resonant actuator at the calibrated drive frequency.

2. The method of claim 1 further comprising sweeping through a plurality of drive frequencies by repeatedly adjusting the drive frequency by the predefined incremental frequency until the induced voltage on the resonant actuator is detected crossing the threshold voltage.

3. The method of claim 1 further comprising storing the calibrated drive frequency in a second memory location.

4. The method of claim 3 wherein if the induced voltage on the resonant actuator is detected crossing the threshold voltage, the method further comprises:
reading the calibrated drive frequency from the second memory location;
storing the calibrated drive frequency as a new initial drive frequency in the first memory location; and
using the new initial drive frequency in a subsequent drive and resonant frequency search.

5. The method of claim 1 wherein the induced voltage on the resonant actuator comprises a back electromotive force generated by the resonant actuator.

6. The method of claim 1 wherein the resonant frequency of the resonant actuator drifts over time, and wherein frequency drift causes a significant drop in vibration strength of the resonant actuator.

7. The method of claim 1 wherein adjusting the drive frequency of the resonant actuator ensures sufficient back electromotive force is generated by the resonant actuator to calibrate its resonant frequency.

8. The method of claim 1 further comprising calibrating the drive frequency to match the resonant frequency of the resonant actuator after the induced voltage on the resonant actuator is detected crossing the threshold voltage.

9. A system for searching for a resonant frequency of a resonant actuator comprising:
a processor comprising one or more memory locations for storing information to be used during processing;
a drive circuit configured to apply a drive signal at a drive frequency to terminals of the resonant actuator for at least a portion of a period of the drive signal;
a comparator configured to detect when an induced voltage on the resonant actuator crosses a threshold voltage after the drive signal is turned off;
a resonance error detection unit configured to assert an auto resonance error signal when the induced voltage on the resonant actuator is not detected crossing the threshold voltage; and
a resonance search controller configured to:
load an initial drive frequency configured to drive a resonant actuator at its resonant frequency from a first memory location;
set the drive frequency equal to the initial drive frequency;
adjust the drive frequency by a predefined incremental frequency to obtain an calibrated drive frequency based on the auto resonance error signal; and
signal the drive circuit to apply the drive signal at the calibrated drive frequency.

10. The system of claim 9 wherein the resonance search controller is further configured to sweep through a plurality of drive frequencies by repeatedly adjusting the drive frequency by the predefined incremental frequency until the induced voltage on the resonant actuator is detected crossing the threshold voltage.

11. The system of claim 9 wherein the calibrated drive frequency is stored in a second memory location.

12. The system of claim 11 wherein if the induced voltage on the resonant actuator is detected crossing the threshold voltage, the resonance search controller is further configured to:
read the calibrated drive frequency from the second memory location;
store the calibrated drive frequency as a new initial drive frequency in the first memory location; and
use the new initial drive frequency in a subsequent drive and resonant frequency search.

13. The system of claim 9 further comprising a clock generator coupled with the drive circuit and configured to provide clock signals to be used by the drive circuit to drive the frequency and period of the drive signal.

14. The system of claim 9 wherein the system is further configured to calibrate the drive frequency to match the resonant frequency of the resonant actuator after the induced voltage on the resonant actuator is detected crossing the threshold voltage.

15. A non-transitory computer readable storage medium tangibly embodying computer code, which when executed by a computer system, causes the computer system to perform operations for searching for a resonant frequency of a resonant actuator, the operations comprising:
loading an initial drive frequency configured to drive the resonant actuator at its resonant frequency from a first memory location;
setting a drive frequency for the resonant actuator equal to the initial drive frequency;
applying a drive signal at the drive frequency to terminals of the resonant actuator for at least a portion of a period of the drive signal;
detecting if an induced voltage on the resonant actuator crosses a threshold voltage after the drive signal is turned off;
if the induced voltage on the resonant actuator is not detected crossing the threshold voltage, the operations further comprise:
signaling an occurrence of an auto resonance error;
adjusting the drive frequency by a predefined incremental frequency to obtain a calibrated drive frequency; and
applying the drive signal to the resonant actuator at the calibrated drive frequency.

16. The computer readable storage medium of claim 15 wherein the operations further comprise sweeping through a plurality of drive frequencies by repeatedly adjusting the drive frequency by the predefined incremental frequency until the induced voltage on the resonant actuator is detected crossing the threshold voltage.

17. The computer readable storage medium of claim 15 wherein the operations further comprise storing the calibrated drive frequency in a second memory location.

18. The computer readable storage medium of claim 17 wherein if the induced voltage on the resonant actuator is detected crossing the threshold voltage, the operations further comprise:
reading the calibrated drive frequency from the second memory location;
storing the calibrated drive frequency as a new initial drive frequency in the first memory location; and
using the new initial drive frequency in a subsequent drive and resonant frequency search.

19. The computer readable storage medium of claim 15 wherein the operations further comprise calibrating the drive frequency to match the resonant frequency of the resonant actuator once the induced voltage on the resonant actuator is detected crossing the threshold voltage.

20. A circuit for searching for a resonant frequency comprising:
means for loading an initial drive frequency configured to drive a resonant actuator at its resonant frequency from a first memory location;
means for setting a drive frequency for the resonant actuator equal to the initial drive frequency;
means for applying a drive signal at the drive frequency to terminals of the resonant actuator for at least a portion of a period of the drive signal;
means for detecting if an induced voltage on the resonant actuator crosses a threshold voltage after the drive signal is turned off;
if the induced voltage on the resonant actuator is not detected crossing the threshold voltage, the circuit means further comprises:
means for signaling an occurrence of an auto resonance error;
means for adjusting the drive frequency by a predefined incremental frequency to obtain a calibrated drive frequency; and
means for applying the drive signal to the resonant actuator at the calibrated drive frequency.

21. The circuit means of claim 20 further comprising means for sweeping through a plurality of drive frequencies including a means for repeatedly adjusting the drive frequency by the predefined incremental frequency until the induced voltage on the resonant actuator is detected crossing the threshold voltage.
